(19) United States
(12) Patent Application Publication
(10) Pub. No.: US 2026/0354177 A1
(43) Pub. Date: Nov. 5, 2026

(54) SEMICONDUCTOR PACKAGE INCLUDING HEAT DISSIPATION STRUCTURE

(71) Applicant: Samsung Electronics Co., Ltd., Suwon-si (KR)

(72) Inventors: Gyosoo Choo, Suwon-si (KR); Junhyoung Kim, Suwon-si (KR); Kwanghoe Heo, Suwon-si (KR); Yeonwook Jung, Suwon-si (KR); Sukkang Sung, Suwon-si (KR); Moosung Kim, Suwon-si (KR); Joonyoung Kwon, Suwon-si (KR)

(73) Assignee: Samsung Electronics Co., Ltd., Suwon-si (KR)

(21) Appl. No.: 19/666,075

(22) Filed: May 1, 2026

(30) Foreign Application Priority Data
May 2, 2025 (KR) 10-2025-0058544

(51) Int. Cl. H10W 40/20; H10B 80/00; H10D 80/30; H10W 40/25; H10W 72/90; H10W 80/00; H10W 90/00; H10W 90/20

(52) U.S. Cl. CPC H10W 40/233; H10B 80/00; H10D 80/30; H10W 40/25; H10W 72/965; H10W 80/312; H10W 90/288; H10W 90/792

(57) ABSTRACT

A semiconductor chip includes a chip substrate having a front surface and a back surface opposing the front surface, a cell array portion disposed on the front surface of the chip substrate, a dam structure disposed on the front surface of the chip substrate and surrounding the cell array portion, a heat dissipation wiring structure provided on the front surface of the chip substrate, a heat dissipation pad disposed on the heat dissipation wiring structure, and disposed between the cell array portion and the dam structure in plan view, a pad dielectric layer surrounding at least a portion of the heat dissipation pad, and a heat dissipation interface connecting the dam structure and the pad dielectric layer.

### CROSS-REFERENCE TO RELATED APPLICATIONS

This present application claims priority to and the benefit under 35 USC § 119(a)-(d) of Korean Patent Application No. 10-2025-0058544, filed on May 2, 2025, in the Korean Intellectual Property Office, the entire disclosure of which is incorporated herein by reference.

### FIELD

Embodiments of the present disclosure relate to a semiconductor package and more particularly to a semiconductor package including a heat dissipation structure or interface.

### BACKGROUND

With the recent rapid increase in demand for semiconductor packages (for example, high bandwidth memory (HBM)) in various industries, research into various methods of improving the integration density of semiconductor packages is being conducted. To this end, sizes of semiconductor chips (for example, memory chips) included in a semiconductor package are being reduced, and a distance between the semiconductor chips is gradually decreasing. However, it is difficult to dissipate heat generated in the semiconductor chips as the integration density of the semiconductor package increases. This causes a degradation in performance of the semiconductor package.

### SUMMARY

According to one or more embodiments, a semiconductor chip includes a chip substrate having a front surface and a back surface opposing the front surface, a cell array portion disposed on the front surface of the chip substrate, a dam structure disposed on the front surface of the chip substrate and surrounding the cell array portion, a heat dissipation wiring structure provided on the front surface of the chip substrate, a heat dissipation pad disposed on the heat dissipation wiring structure, and disposed between the cell array portion and the dam structure in plan view, a pad dielectric layer surrounding at least a portion of the heat dissipation pad, and a heat dissipation interface connecting the dam structure and the pad dielectric layer.

According to one or more embodiments, a semiconductor chip includes a chip substrate having a front surface and a back surface opposing the front surface, a cell array portion disposed on the front surface of the chip substrate, a dam structure disposed on the front surface of the chip substrate and surrounding the cell array portion, the dam structure including a dam body portion disposed on the front surface of the chip substrate and a dam head portion disposed on the dam body portion, a conductive wiring structure provided on the front surface of the chip substrate, a conductive pad disposed on the conductive wiring structure, and disposed between the cell array portion and the dam structure in plan view, a heat dissipation interface extending from the dam head portion to be disposed on the cell array portion, and an insulating material disposed between the heat dissipation interface and the cell array portion.

According to one or more embodiments, a semiconductor package includes a plurality of stacked semiconductor chips. At least one of the semiconductor chips may include a chip substrate, a cell array portion disposed on one surface of the chip substrate, a dam structure disposed on the one surface of the chip substrate and surrounding the cell array portion, a heat dissipation wiring structure provided on the one surface of the chip substrate, a heat dissipation pad disposed on the heat dissipation wiring structure, and disposed between the cell array portion and the dam structure in plan view, and a pad dielectric layer surrounding at least a portion of the heat dissipation pad. The heat dissipation pad extends toward the dam structure to allow the pad dielectric layer to be in contact with the dam structure, and the semiconductor chips are stacked to expose the heat dissipation pad.

### BRIEF DESCRIPTION OF THE DRAWINGS

FIG. 1 is a perspective view of a semiconductor chip according to one or more embodiments.

FIG. 2 is a plan view of the semiconductor chip of FIG. 1.

FIG. 3 is a cross-sectional view taken along line I-I′ of FIG. 2.

FIG. 4 is a cross-sectional view taken along line II-II′ of FIG. 2.

FIG. 5 is a cross-sectional view taken along line III-III′ of FIG. 2.

FIG. 6 is a perspective view illustrating a semiconductor package in which the semiconductor chips of FIG. 1 are disposed.

FIG. 7 is a plan view of a semiconductor chip according to one or more embodiments.

FIG. 8 is a cross-sectional view taken along line IV-IV′ of FIG. 7.

FIG. 9 is a cross-sectional view of a semiconductor chip according to one or more embodiments and corresponds to the cross-sectional view taken along line II-II′ of FIG. 2.

FIGS. 10-21 are cross-sectional views illustrating a method of manufacturing a semiconductor chip according to one or more embodiments.

### DETAILED DESCRIPTION

The following description with reference to the accompanying drawings is provided to assist in a comprehensive understanding of various embodiments of the present disclosure.

Embodiments of the present disclosure provide a semiconductor package configured to reduce heat generated therein.

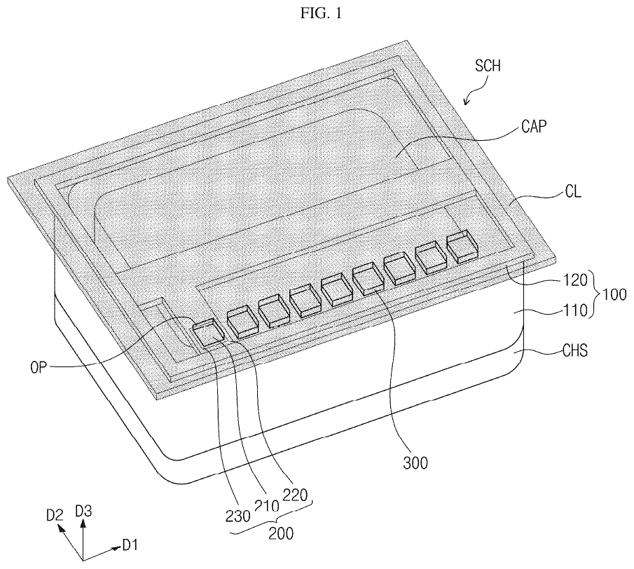

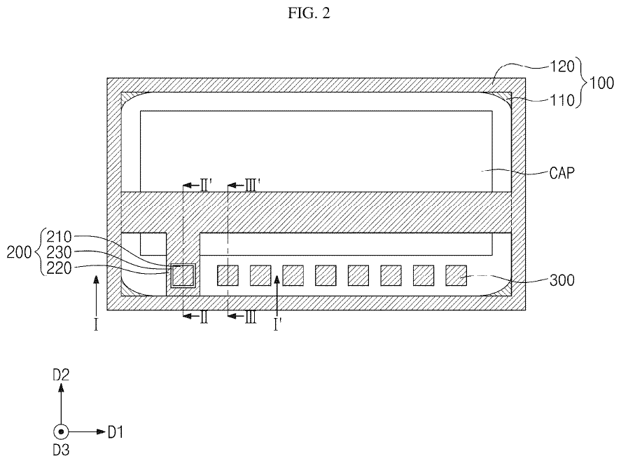

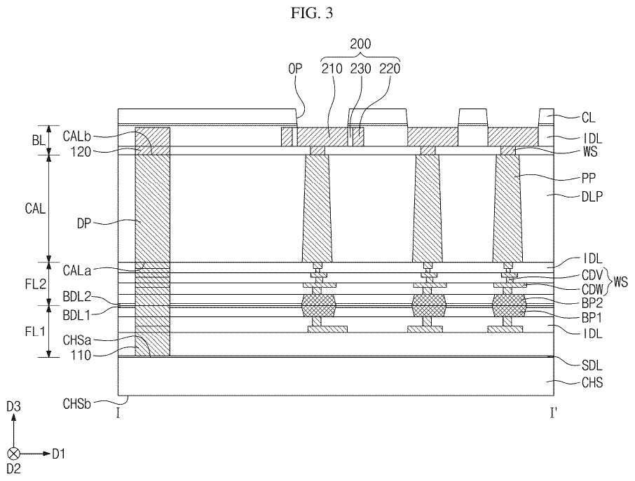

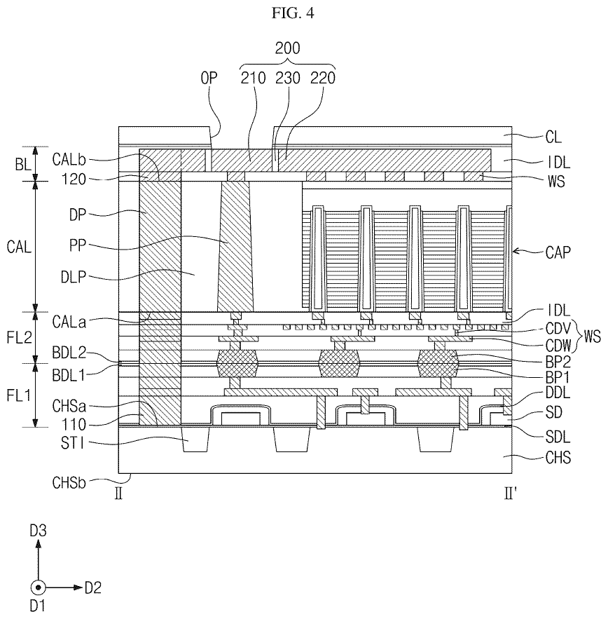

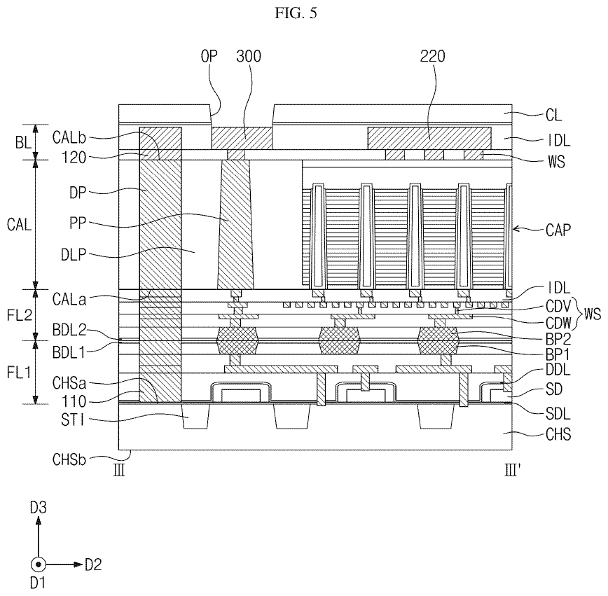

FIG. 1 is a perspective view of a semiconductor chip according to one or more embodiments. FIG. 2 is a plan view of the semiconductor chip of FIG. 1. FIG. 3 is a cross-sectional view taken along line I-I′ of FIG. 2. FIG. 4 is a cross-sectional view taken along line II-II′ of FIG. 2. FIG. 5 is a cross-sectional view taken along line III-III′ of FIG. 2.

Referring to FIG. 1, a semiconductor chip SCH may be formed. The semiconductor chip SCH may include a chip substrate CHS, a cell array portion CAP provided on a front surface of the chip substrate CHS, a dam structure 100 provided on a front surface of the chip substrate CHS and surrounding the cell array portion CAP, a heat dissipation structure 200 provided on the front surface of the chip substrate CHS and configured to transfer heat of the chip substrate CHS to the dam structure 100, and a conductive pad 300.

Referring to FIGS. 1-5, the semiconductor chip SCH may include a chip substrate CHS having a front surface and a rear surface facing the front surface, a first front surface layer FL1 disposed on a front surface CHSa of the chip substrate CHS, a cell array layer CAL having a front surface and a rear surface facing the front surface, a second front surface layer FL2 disposed on a front surface CALa of the cell array layer CAL, a rear surface layer BL disposed on a rear surface CALb of the cell array layer CAL, and a cover layer CL disposed on the rear surface layer BL.

The chip substrate CHS may be a doped or undoped silicon (Si) substrate. The chip substrate CHS is not limited thereto and may be a substrate containing an element such as germanium or a compound such as silicon carbide (SiC), gallium arsenide (GaAs), indium arsenide (InAs), and indium phosphide (InP). Alternatively, the chip substrate CHS may have a silicon-on-insulator (SOI) structure. In one or more embodiments, the chip substrate CHS may include a well doped with an impurity, which is a conductive region, or an impurity-doped structure. The chip substrate CHS may also have various isolation structures such as a shallow trench isolation pattern (STI) structure.

The first front surface layer FL1 having at least one semiconductor device SD may be formed on the front surface CHSa of the chip substrate CHS. The semiconductor devices SD may be classified into memory devices and logic devices.

In one or more embodiments, a memory device may be a volatile memory device or a non-volatile memory device. For example, the volatile memory device may include a memory device such as a dynamic random access memory (DRAM), a static RAM (SRAM), a thyristor RAM (TRAM), a zerocapacitor RAM (ZRAM), or a twin transistor RAM (TTRAM). For example, the non-volatile memory device may include a memory device such as a flash memory, a magnetic RAM (MRAM), a spin-transfer torque MRAM (STT-MRAM), a ferroelectric RAM (FRAM), a phase change RAM (PRAM), a resistive RAM (RRAM), a nanotube RRAM, a polymer RAM, a nano floating gate memory, a holographic memory, a molecular electronics memory, or an insulator resistance change memory.

In one or more embodiments, a logic device may be implemented as a microprocessor, a graphics processor, a signal processor, a network processor, an audio codec, a video codec, an application processor, or a system on chip (SoC), but embodiments are not limited thereto.

The first front surface layer FL1 may be disposed on the front surface CHSa of the chip substrate CHS and may include a substrate dielectric layer SDL covering the chip substrate CHS, the semiconductor device SD disposed on the substrate dielectric layer SDL, a device dielectric layer DDL covering the semiconductor device SD, an interlayer dielectric layer IDL covering the device dielectric layer DDL, a wiring structure WS disposed on the interlayer dielectric layer IDL and connected to the semiconductor devices SD, a first bonding dielectric layer BDL1 covering the uppermost interlayer dielectric layer IDL of the first front surface layer FL1, a first bonding pad BP1 disposed in the uppermost interlayer dielectric layer IDL and the first bonding dielectric layer BDL1 of the first front surface layer FL1, and a dam structure 100.

The wiring structure WS may have a multilayer wiring structure in which an insulating layer and a conductive wiring CDW are alternately disposed. The conductive wirings CDW of each layer may include conductive vias CDV disposed in a direction perpendicular to the front surface CHSa of the chip substrate CHS. The conductive wiring CDW and the conductive via CDV may include a conductive material including at least one of aluminum (Al), copper (Cu), nickel (Ni), tungsten (W), silver (Ag), platinum (Pt), and gold (Au). In one or more embodiments, the name of the wiring structure WS may vary depending on a pad to be coupled and/or purposes thereof. For example, when the wiring structure WS is connected to a heat dissipation pad 210, the wiring structure WS may be a heat dissipation wiring structure. For example, when the wiring structure WS is connected to the conductive pad 300, the wiring structure WS may be a conductive wiring structure.

Each of the dielectric layers SDL, DDL, IDL, BDL1, and BDL2 may be formed of a low-κ dielectric material. The low-κ dielectric material is a material having a lower dielectric constant than a silicon oxide. When the low-κ dielectric material is used as the interlayer dielectric layer IDL in the semiconductor device SD, an insulating capability may be improved, which may affect realizing a high integration density and/or a high speed of the semiconductor device SD. In addition, the dielectric layers SDL, DDL, IDL, BDL1, BDL2 may include a non-conductive film (NCF), a non-conductive paste (NCP), an insulating polymer, or an epoxy resin. In one or more embodiments, the dielectric layers SDL, DDL, IDL, BDL1, BDL2 may include a film having at least one of a silicon element (Si), a nitrogen element (N), and an oxygen element (O) as a constituent element. For example, the dielectric layers SDL, DDL, IDL, BDL1, and BDL2 may include an oxide film, a nitride film, an oxynitride film, a silicon film, a silicon oxide film, or a silicon oxynitride film. In one or more embodiments, the bonding dielectric layers BDL1 and BDL2 may include a film having an oxygen element O as a constituent element and may be bonded to each other.

The cell array layer CAL may include a cell array portion CAP, a dam portion DP spaced apart from and surrounding the cell array portion CAP, a pad portion PP disposed in a portion between the dam portion DP and the cell array portion CAP, and a dielectric portion DLP disposed between the cell array portion CAP, the dam portion DP, and the pad portion PP. The dam portion DP may include a portion of the dam structure 100 disposed in the cell array layer CAL. The pad portion PP may include the conductive vias CDV connected to the heat dissipation pad 210 and/or the conductive pad 300 among the wiring structure WS disposed in the cell array layer CAL.

The second front surface layer FL2 may be formed on the front surface CALa of the cell array layer CAL. The second front surface layer FL2 may be disposed on the front surface CALa of the cell array layer CAL, and may include an interlayer dielectric layer IDL covering the cell array layer CAL, a wiring structure WS disposed on the interlayer dielectric layer IDL and connected to the cell array portion CAP, a second bonding dielectric layer BDL2 covering the uppermost interlayer dielectric layer IDL of the second front surface layer FL2, a second bonding pad BP2 disposed in the uppermost interlayer dielectric layer IDL and the second bonding dielectric layer BDL2 of the first front surface layer FL2, and a dam structure 100.

The first bonding pad BP1 may be disposed in the uppermost interlayer dielectric layer IDL and the first bonding dielectric layer BDL1 of the first front surface layer FL1, and the first bonding pad BP1 may be electrically connected to the semiconductor device SD through the wiring structure WS. The second bonding pad BP2 may be disposed in the uppermost interlayer dielectric layer IDL and the second bonding dielectric layer BDL2 of the second front surface layer FL2, and the second bonding pad BP2 may be electrically connected to the cell array portion CAP and/or the pad portion PP through the wiring structure WS.

The bonding pads BP1 and BP2 may electrically connect the semiconductor device SD and the cell array portion CAP and may electrically connect the semiconductor device SD and the pad portion PP. In addition, heat of the chip substrate CHS may be transferred to the heat dissipation structure 200 through the bonding pads BP1 and BP2. In one or more embodiments, the bonding pads BP1 and BP2 may include a conductive material. For example, the bonding pads BP1 and BP2 may include a conductive material containing at least one of aluminum (Al), copper (Cu), nickel (Ni), tungsten (W), silver (Ag), platinum (Pt), and gold (Au), or a conductive paste including the conductive material.

The back surface layer BL may be formed on the back surface CALb of the cell array layer CAL. The back surface layer BL may be disposed on the back surface CALb of the cell array layer CAL and may include an interlayer dielectric layer IDL covering the cell array layer CAL, a wiring structure WS disposed on the interlayer dielectric layer IDL and connected to the semiconductor device SD, a dam structure 100, a heat dissipation structure 200 transferring heat of the chip substrate CHS to the dam structure 100, and a conductive pad 300.

A cover layer CL may be formed on the back surface layer BL. The cover layer CL is disposed on the back surface layer BL and may include an opening OP formed by recessing a portion of the cover layer CL corresponding to a location vertically overlapping a portion of the heat dissipation structure 200 and/or a position vertically overlapping the conductive pad 300. In one or more embodiments, the heat dissipation pad 210 and the conductive pad 300 may be exposed by the opening OP.

The dam structure 100 may be disposed in the first front surface layer FL1, the second front surface layer FL2, the cell array layer CAL, and the back surface layer BL. The dam structure 100 is disposed on the chip substrate CHS and may be disposed to surround at least a portion of the semiconductor devices SD. As illustrated in FIGS. 2, 4, and 5, a dam structure 100 of one or more embodiments may be disposed to completely surround the semiconductor devices SD. In addition, the dam structure 100 may be disposed in the cell array layer CAL and may be disposed to surround at least a portion of the cell array portion CAP. As illustrated in FIGS. 2, 4, and 5, a dam structure 100 ofone or more embodiments may be disposed to completely surround the cell array portion CAP. The dam structure 100 may extend from the first front surface layer FL1 and be disposed on the back surface layer BL, and the dam structure 100 may have at least two layers. Embodiments are not limited thereto, so that the dam structure 100 may have a single layer.

In one or more embodiments, the dam structure 100 may include a dam body portion 110 and a dam head portion 120. The dam body portion 110 may be a portion of the dam structure 100 disposed in the first front surface layer FL1, the second front surface layer FL2, and the cell array layer CAL, and the dam head portion 120 may be a portion of the dam structure 100 disposed in the back surface layer BL. The dam body portion 110 of the first front surface layer FL1 may be disposed on the substrate dielectric layer SDL. A lower surface of the dam body portion 110 of the first front surface layer FL1 may be coplanar with a lower surface of the semiconductor device SD. For example, the lower surface of the dam body portion 110 of the first front surface layer FL1 may have the same location level as the lower surface of the semiconductor device SD. The dam head portion 120 of the back surface layer BL may be disposed on the interlayer dielectric layer IDL. An upper surface of the dam head portion 120 of the back surface layer BL may be coplanar with an upper surface of the heat dissipation pad 210. In addition, the upper surface of the dam head portion 120 of the back surface layer BL may be coplanar with an upper surface of the heat dissipation interface 220. For example, the upper surface of the dam head portion 120 of the back surface layer BL may have the same location level as the upper surface of the heat dissipation pad 210. In addition, the upper surface of the dam head portion 120 of the back surface layer BL may have the same location level as the upper surface of the heat dissipation interface 220.

In one or more embodiments, the dam structure 100 may be formed by bonding at least two layers. A process of forming the dam structure 100 may be performed along with a process of forming the wiring structure WS, and thus the dam structure 100 may include the same or a similar number of layers as the number of multilayers constituting the wiring structure WS. For example, a height of each of the layers of the dam structure 100 may be substantially the same as a height of each of the conductive wirings CDW and the conductive vias CDV.

In one or more embodiments, the dam structure 100 may include a material having a high thermal conductivity, which includes at least one of aluminum (Al), copper (Cu), nickel (Ni), tungsten (W), silver (Ag), platinum (Pt), and gold (Au). In addition, the dam structure 100 may include a material available as the wiring structure WS other than the above-mentioned materials, and may include any material available as the wiring structure WS or having a high thermal conductivity.

The heat dissipation structure 200 may include a heat dissipation pad 210 connected to the wiring structure WS and configured to dissipate heat of the chip substrate CHS, a heat dissipation interface 220 disposed to surround the heat dissipation pad 210 and configured to receive heat from the heat dissipation pad 210, and a pad dielectric layer 230 disposed between the heat dissipation pad 210 and the heat dissipation interface 220.

The heat dissipation pad 210 may be disposed in the back surface layer BL, and may be disposed in a portion between the dam structure 100 and the cell array portion CAP from a planar perspective. For example, the heat dissipation pad 210 may not vertically overlap with the dam structure 100 and/or the cell array portion CAP. In FIGS. 2-4, the heat dissipation pad 210 is illustrated as being a single heat dissipation pad, but embodiments are not limited thereto. Therefore, the heat dissipation pad 210 may include two or more heat dissipation pads. In one or more embodiments, the heat dissipation pad 210 may receive heat generated in the chip substrate CHS through the wiring structure WS connected to the chip substrate CHS. The heat may be generated at different points based on the operation of the semiconductor device, but the heat may move along the chip substrate CH. Therefore, at least one heat dissipation pad 210 may dissipate the heat generated in the semiconductor chip SCH.

The heat dissipation interface 220 may be disposed in the back surface layer BL and may be disposed to surround at least a portion of the heat dissipation pad 210 from a planar perspective. As illustrated in FIGS. 2-4, a heat dissipation interface 220 of one or more embodiments may be disposed to completely surround the heat dissipation pad 210. For example, the heat dissipation interface 220 may be disposed to completely surround the entire pad dielectric layer 230 in plan view. At least a portion of the heat dissipation interface 220 may be disposed to be in contact with the dam structure 100. The heat dissipation interface 220 is not limited as long as it is configured to transfer heat to the dam structure 100. Therefore, as illustrated in FIG. 2, the heat dissipation interface 220 may be in contact with the dam structure 100 at three points, may be in contact with the dam structure 100 at one point or two points, and may be in contact with the dam structure 100 at four or more points. In addition, the heat dissipation interface 220 may be spaced apart from the dam structure 100, and a dielectric layer may be provided between the heat dissipation interface 220 and the dam structure 100. In one or more embodiments, the heat dissipation interface 220 may receive heat of the heat dissipation pad 210, and the heat dissipation interface 220 may provide the received heat to the dam structure 100. For example, including the heat dissipation interface 220 enables the heat of the heat dissipation pad 210 to be provided to the dam structure 100, and causes the surface area exposed to the outside of the chip to be significantly increased. As a result, the heat may be dissipated rapidly. In addition, the heat dissipation interface 220 may provide heat directly reaching the heat dissipation interface 220 to the dam structure 100, other than the heat provided from the heat dissipation pad 210.

In one or more embodiments, the heat dissipation interface 220 may be disposed to be spaced apart from the heat dissipation pad 210. As will be described later, the heat dissipation pad 210 and the heat dissipation interface 220 include materials with high thermal conductivity. However, materials having high thermal conductivity generally also have high conductivity, so that the heat dissipation pad 210 and the heat dissipation interface 220 may include materials having high conductivity. The heat dissipation pad 210 is electrically connected to the semiconductor device SD, so that an insulating material may be further included between the heat dissipation pad 210 and the heat dissipation interface 220 to block an electrical connection between the semiconductor device SD and the heat dissipation interface 220.

In one or more embodiments, a process of forming the heat dissipation pad 210 and the heat dissipation interface 220 may be performed along with a process of forming a portion of the dam structure 100, so that the heat dissipation pad 210 and the heat dissipation interface 220 may include at least one layer having the same or a similar height as a portion of the dam structure 100. For example, the height of the heat dissipation pad 210 and the heat dissipation interface 220 may be substantially the same as the height of the uppermost dam head portion 120. A lower surface of the heat dissipation pad 210 and a lower surface of the heat dissipation interface 220 and a lower surface of the uppermost dam head portion 120 may be coplanar with each other, and may have the same location level.

In one or more embodiments, each of the heat dissipation pad 210 and the heat dissipation interface 220 may include a material having a high thermal conductivity, which includes at least one of aluminum (Al), copper (Cu), nickel (Ni), tungsten (W), silver (Ag), platinum (Pt), and gold (Au). In addition, each of the heat dissipation pad 210 and the heat dissipation interface 220 may include a material available as the wiring structure WS other than the above-mentioned materials, and may include any material available as the wiring structure WS or having a high thermal conductivity.

The pad dielectric layer 230 may be disposed in the back surface layer BL and may be disposed to surround at least a portion of the heat dissipation pad 220 in plan view. As illustrated in FIGS. 2-4, the pad dielectric layer 230 of one or more embodiments may be disposed to completely surround the heat dissipation pad 210. For example, the pad dielectric layer 230 may be disposed to completely surround the entire heat dissipation pad 210 in plan view. In addition, the pad dielectric layer 230 may be disposed between the heat dissipation pad 210 and the heat dissipation interface 220. The pad dielectric layer 230 may block an electrical connection between the heat dissipation pad 210 and the heat dissipation interface 220 to control only heat to be transferred from the heat dissipation pad 210 to the heat dissipation interface 220. In one or more embodiments, the pad dielectric layer 230 may be formed of a low dielectric constant material, and the pad dielectric layer 230 may include a non-conductive film (NCF), a non-conductive paste (NCP), an insulating polymer, or an epoxy resin, and the pad dielectric layer 230 may include a layer having at least one of a silicon element (Si), a nitrogen element (N), and an oxygen element (O) as a constituent element.

The conductive pad 300 may be disposed in the back surface layer BL and may be disposed in a portion between the dam structure 100 and the cell array portion CAP in plan view. For example, the conductive pad 300 may not vertically overlap with the dam structure 100 and/or the cell array portion CAP. Although FIGS. 2, 3, and 5 illustrate a plurality of conductive pads 300, embodiments are not limited thereto. Therefore, seven or less conductive pads 300 may be disposed, one conductive pad 300 may be disposed, or nine or more conductive pads 300 may be disposed. In addition, the conductive pad 300 may be electrically connected to the semiconductor device SD through the wiring structure WS.

In one or more embodiments, a process of forming the conductive pad 300 may be performed along with a process of forming a portion of the dam structure 100. Therefore, the conductive pad 300 may include at least one layer having the same or a similar height as a portion of the dam structure 100. For example, the height of the conductive pad 300 may be substantially the same as the height of the uppermost dam head portion 120. A lower surface of the conductive pad 300 and a lower surface of the uppermost dam head portion 120 may be coplanar with each other and may have the same location level.

In one or more embodiments, the conductive pad 300 may include a material having a high conductivity, which includes at least one of aluminum (Al), copper (Cu), nickel (Ni), tungsten (W), silver (Ag), platinum (Pt), and gold (Au). In addition, the conductive pad 300 may include a material available as the wiring structure WS other than the above-mentioned materials, and may include any material available as the wiring structure WS or having a high conductivity.

In one or more embodiments, the heat dissipation pad 210 and the conductive pad 300 are different in whether the pad dielectric layer 230 is disposed and a degree of adjacency to the heat dissipation interface 220 and, in other respects, are illustrated as being the same or similar in terms of a formation process, constituent materials, a location level from a cross-sectional perspective, and so on, but the heat dissipation pad 210 and the conductive pad 300 may have different constituent materials, and may also have different location levels in cross-sectional view. For example, the heat dissipation pad 210 may be formed of a material having a high thermal conductivity and a low conductivity, and the conductive pad 300 may be formed of a material having a low thermal conductivity and a high conductivity. However, the thermal conductivity and the conductivity of a material generally increase in proportion to each other, so that the heat dissipation pad 210 and the conductive pad 300 according to one or more embodiments may be formed of the same or similar materials.

FIG. 6 is a perspective view illustrating a semiconductor package in which the semiconductor chips of FIG. 1 are disposed.

Referring to FIGS. 1 and 6, a semiconductor package SPK may include a package substrate PKS, the semiconductor chips SCH disposed on the package substrate PKS, and a package pad PKP disposed on the package substrate PKS, and the semiconductor chips SCH may be electrically connected to each other through the conductive pad 300 and a connecting wiring CW in a wire shape. In addition, the semiconductor chips SCH may provide heat of the heat dissipation pad 210 to the package pad PKP through the heat dissipation pad 210 and the connecting wiring CW in a wire shape.

The package substrate PKS may transfer a signal from a semiconductor chip SCH, disposed on an upper side, to the outside and transfer a signal and power from the outside to the semiconductor chip SCH. The package substrate PKS includes wirings for transferring a signal, power, or the like. The wirings of the package substrate PKS may include a wiring structure, not illustrated, including a connecting wiring CW in a wire shape, a package pad PKP, or the like, a connecting wiring, a wiring pad, a conductive pad, or the like. In one or more embodiments, the package substrate PKS may include an insulating material. For example, the package substrate PKS may include an insulating resin. The insulating resin may include a thermosetting resin such as an epoxy resin, a thermoplastic resin such as a polyimide, or a resin in which an inorganic filler, or the like, is impregnated in such resins. For example, the package substrate PKS may include a photosensitive resin such as a photoimageable dielectric (PID). The package substrate PKS may include insulating layers, not illustrated, stacked in a vertical direction. A boundary between the insulating layers may be unclear depending on a process. In one or more embodiments, the package substrate PKS may be a doped or undoped silicon (Si) substrate. The package substrate PKS is not limited thereto and may be a substrate containing an element such as germanium or a compound such as silicon carbide (SiC), gallium arsenide (GaAs), indium arsenide (InAs), and indium phosphide (InP).

Various active or passive micro-electronic devices may be additionally provided on the package substrate PKS. For example, the package substrate PKS may include a complementary metal-insulator-semiconductor (CMOS) transistor, a metal-oxide-semiconductor field effect transistor (MOSFET), a large scale integration (LSI), a CMOS imaging sensor (CIS), a micro-electro-mechanical system (MEMS), or the like.

The semiconductor package SPK may have a connecting wiring connecting the semiconductor chips SCH and the package pad PKP. In one or more embodiments, the connecting wiring may include a conductive material. For example, the connecting wiring may include a metal containing tin (Sn), iron (Fe), nickel (Ni), or alloys thereof, but embodiments are not limited thereto. The connecting wiring may be a structure in a pillar shape, may be a wire ball, or may be in a wire shape. The connecting wiring CW in a wire shape may be disposed to extend in a direction perpendicular to an upper surface of the package substrate PKS, but embodiments are not limited thereto. The connecting wiring CW in a wire shape may extend in a direction forming an arbitrary angle with the upper surface of the package substrate PKS to connect the package substrate PKS and the semiconductor chip SCH. In addition, the connecting wiring CW in a wire shape may connect the semiconductor chips SCH to each other.

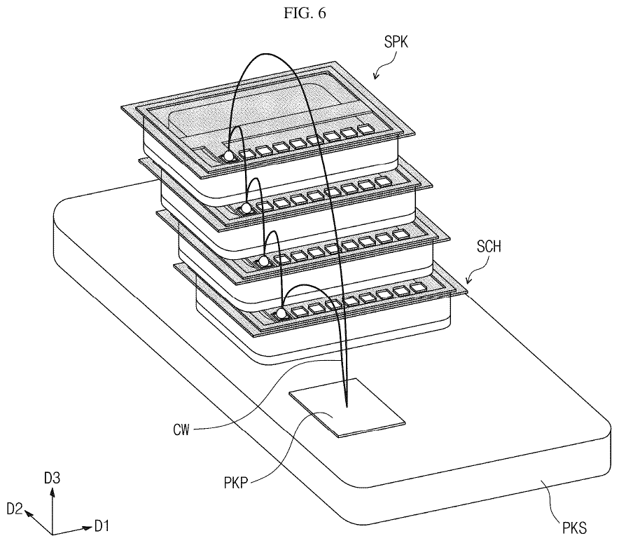

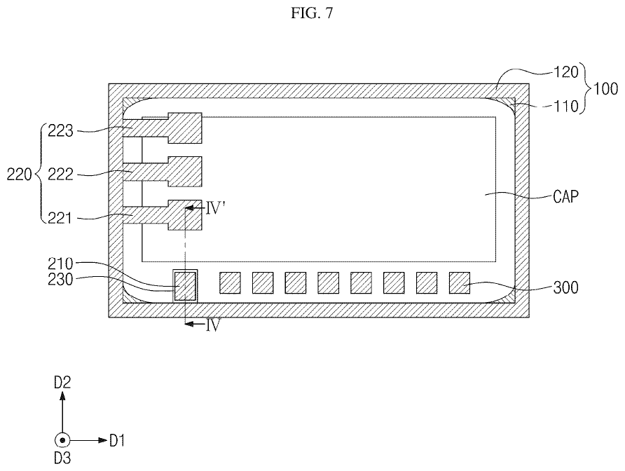

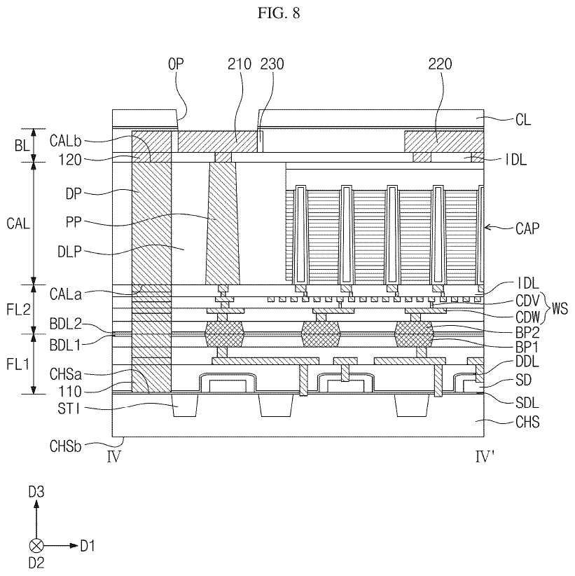

FIG. 7 is a plan view of a semiconductor chip according to one or more embodiments. FIG. 8 is a cross-sectional view taken along line IV-IV′ of FIG. 7.

Referring to FIGS. 7 and 8, the heat dissipation pad 210 may extend in a direction of the dam structure 100 in plan view, and the pad dielectric layer 230 may surround the extended heat dissipation pad 210 and be disposed between the heat dissipation pad 210 and the dam structure 100. For example, the heat dissipation pad 210 may transfer heat to the dam structure 100 through the pad dielectric layer 230. Although the size of the heat dissipation pad 210 of FIG. 2, which has been described, is illustrated as being the same or similar as the size of the conductive pad 300 in plan view, the size of the heat dissipation pad 210 of FIG. 7 may be illustrated as being larger than the size of the conductive pad 300 in plan view. However, a relative difference between the size of the heat dissipation pad 210 and the size of the conductive pad 300 is not limited thereto, so that the size of the heat dissipation pad 210 may also be illustrated as being smaller than the size of the conductive pad 300 in plan view.

The heat dissipation interface 220 may be changed into various shapes in plan view, and embodiments are not limited thereto. The heat dissipation interface 220 may be disposed to surround the heat dissipation pad 210 as illustrated in FIG. 2, and may be disposed to be spaced apart from the heat dissipation pad 210 and the pad dielectric layer 230 as illustrated in FIG. 7. For example, the heat dissipation interface 220 may provide heat transferred through the chip substrate CHS and/or the interlayer dielectric layer IDL to the dam structure 100. In addition, the heat dissipation interface 220 may include heat dissipation interfaces 221, 222, and 223. In one or more embodiments, the heat dissipation interface 220 of FIG. 7 is illustrated as three heat dissipation interfaces 221, 222, and 223, but embodiments are not limited thereto. For example, the heat dissipation interface 220 may include two heat dissipation interfaces. For example, the heat dissipation interface 220 may include four or more heat dissipation interfaces. In one or more embodiments, at least a portion of the heat dissipation interface 220 may be in contact with the dam structure 100. For example, each of the heat dissipation interfaces 221, 222, and 223 of FIG. 7 may have one side in contact with the dam structure 100. For example, the heat dissipation interface 220 of FIG. 2 may have three sides in contact with the dam structure 100. Embodiments are not limited thereto, so that the heat dissipation interface 220 may have two sides in contact with the dam structure 100 and may have four or more sides in contact with the dam structure 100.

In one or more embodiments, the heat dissipation interface 220 may also be spaced apart from the dam structure 100 to an extent that the heat dissipation interface 220 is easy to transfer heat to the dam structure 100. When the heat dissipation interface 220 is spaced apart from the dam structure 100 (not illustrated), a material having a high thermal conductivity and/or an insulating material may be further included between the heat dissipation interface 220 and the dam structure 100.

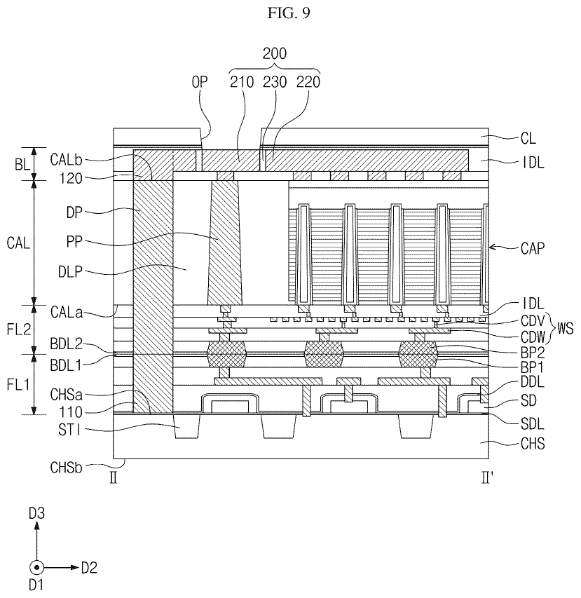

FIG. 9 is a cross-sectional view of a semiconductor chip according to one or more embodiments, corresponding to a cross-sectional view taken along line II-II′ of FIG. 2.

Referring to FIG. 9, the dam structure 100 may be formed in a single layer in the first front surface layer FL1, the dam structure 100 may be formed in a single layer in the second front surface layer FL2 and the cell array layer CAL, and the dam structure 100 may be formed in a single layer in the back surface layer BL. In one or more embodiments, a process of forming the dam structure 100 may be performed along with a process of forming the wiring structure WS, and the dam structure 100 may include the same or a similar number of layers as the number of multilayers constituting the wiring structure WS. In addition, a process of forming the dam structure 100 of the first front surface layer FL1 may be performed after the first bonding dielectric layer BDL1 of the first front surface layer FL1 is covered, and the dam structure 100 of the first front surface layer FL1 may be a single layer in the first front surface layer FL1. In addition, a process of forming the dam structure 100 of the second front surface layer FL2 and the cell array layer CAL may be performed after the second bonding dielectric layer BDL2 of the second front surface layer FL2 is covered, and the dam structure 100 of the second front surface layer FL2 may be a single layer in the second front surface layer FL2 and the cell array layer CAL. In addition, a process of forming the dam structure 100 of the back surface layer BL may be performed together with a process of forming the heat dissipation pad 210, the conductive pad 300, and the heat dissipation interface 220, and the dam structure 100 of the back surface layer BL may be a single layer in the back surface layer BL. In addition, in FIG. 9, the dam structure 100 is illustrated as being divided into the first front surface layer FL1, the second front surface layer FL2 and the cell array layer CAL, and the back surface layer BL, but may appear as a single layer in an actual cross section. In addition, the dam structure 100 in an actual cross section may include a dam body portion 110 penetrating through the first front surface layer FL1, the second front surface layer FL2, and the cell array layer CAL, and a dam head portion 120 disposed in the back surface layer BL.

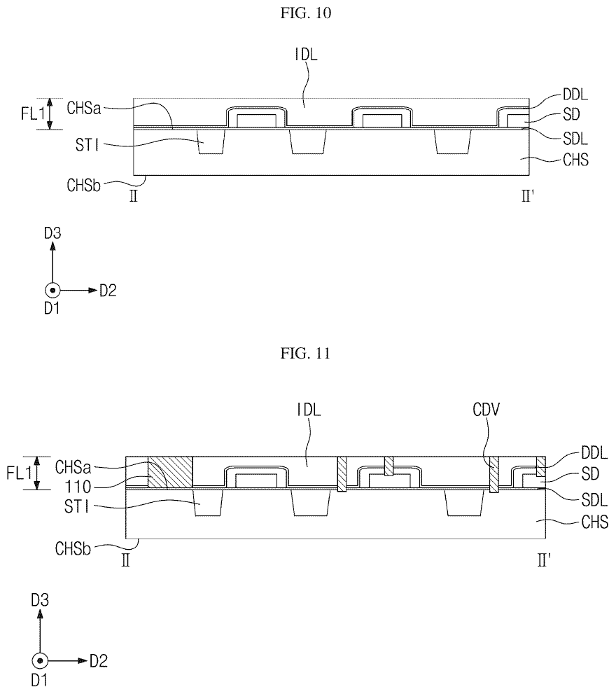

FIGS. 10-21 are cross-sectional views illustrating a method of manufacturing a semiconductor chip according to one or more embodiments.

Referring to FIG. 10, a chip substrate CHS having a front surface CHSa and a back surface CHSb facing the front surface CHSa may be provided, and a shallow trench isolation pattern STI may be formed in the chip substrate CHS. After the shallow trench isolation pattern STI is formed, a substrate dielectric layer SDL may be formed on the front surface CHSa of the chip substrate CHS. The semiconductor devices SD may be formed on the front surface CHSa of the chip substrate CHS with the substrate dielectric layer SDL therebetween. A device dielectric layer DDL may be formed to cover the semiconductor devices SD and the substrate dielectric layer SDL, and an interlayer dielectric layer IDL may be formed to cover the device dielectric layer DDL. The first front surface layer FL1 may include components disposed on the front surface CHSa of the chip substrate CHS. For example, the first front surface layer FL1 may include the substrate dielectric layer SDL, the semiconductor devices SD, the device dielectric layer DDL, and the interlayer dielectric layer IDL

Referring to FIG. 11, a portion of the conductive vias CDV may be formed in the interlayer dielectric layer IDL, the device dielectric layer DDL, the substrate dielectric layer SDL, and the chip substrate CHS. A trench penetrating through the interlayer dielectric layer IDL, the device dielectric layer DDL, and the substrate dielectric layer SDL while etching a portion of the chip substrate CHS may be formed, and the trench may be filled with the portion of the conductive vias CDV. In addition, the other remaining portion of the conductive vias CDV may be formed in the interlayer dielectric layer IDL, the device dielectric layer DDL, and the semiconductor device SD. A trench penetrating the interlayer dielectric layer IDL and the device dielectric layer DDL while etching a portion of the semiconductor device SD may be formed, and the trench may be filled with the other remaining portion of the conductive vias CDV. The dam body portion 110 may be formed within the interlayer dielectric layer IDL and the device dielectric layer DDL. A trench may be formed to penetrate through the interlayer dielectric layer IDL and the device dielectric layer DDL. The trench may be filled with the dam body portion 110, and the dam body portion 110 may be formed on the substrate dielectric layer SDL. The first front surface layer FL1 according to one or more embodiments may include the substrate dielectric layer SDL, the semiconductor devices SD, the device dielectric layer DDL, the interlayer dielectric layer IDL, the conductive vias CDV, and the dam body portion 110.

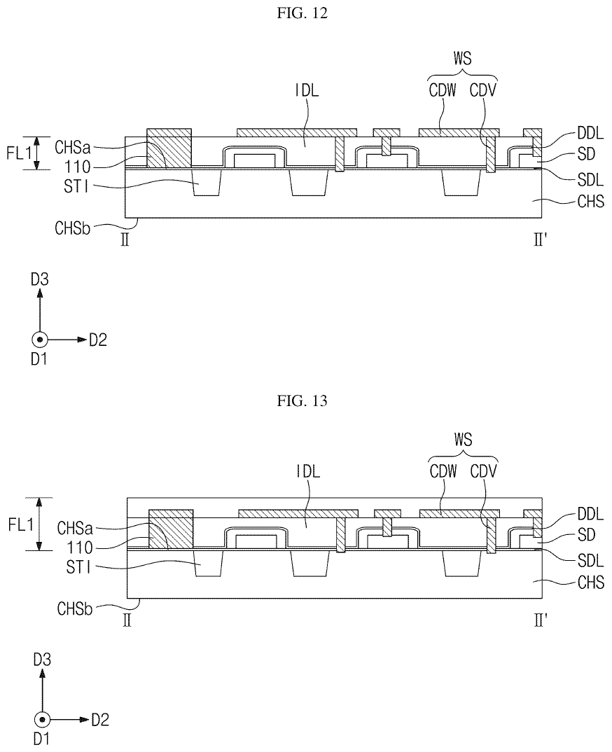

Referring to FIGS. 12 and 13, the conductive wirings CDW may be formed on the interlayer dielectric layer IDL. The conductive wirings CDW may be disposed to vertically overlap the conductive vias CDV. A portion of the dam body portion 110 may be formed on the interlayer dielectric layer IDL. The portion of the dam body portion 110 may be disposed to vertically overlap with the dam body portion 110, and the portion of the dam body portion 110 may be included in the dam body portion 110. In addition, the interlayer dielectric layer IDL may be formed to cover the conductive wirings CDW.

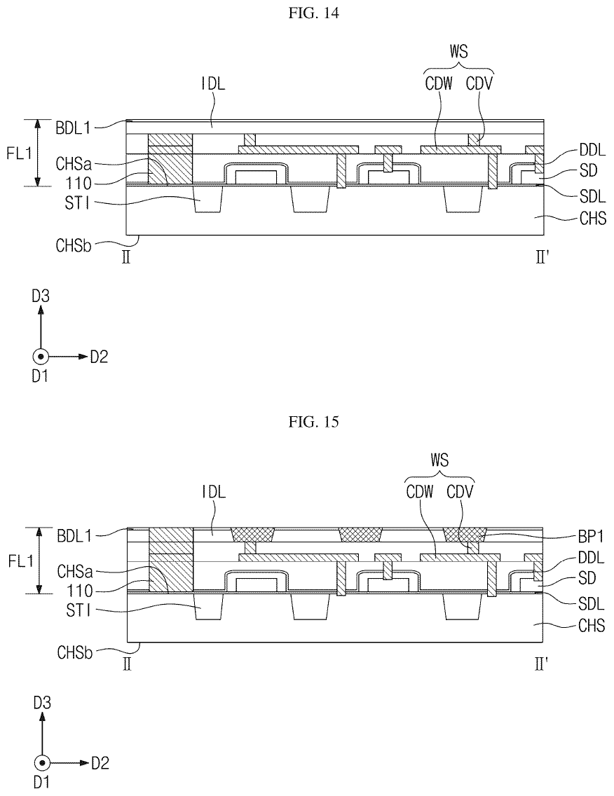

Referring to FIG. 14, the conductive vias CDV may be formed in the interlayer dielectric layer IDL, and the trench penetrating through the interlayer dielectric layer IDL may expose the conductive wirings CDW. The conductive vias CDV may fill the trench, and the conductive vias CDV may be formed on the conductive wirings CDW. The conductive vias CDV and the conductive wirings CDW may be electrically connected. A portion of the dam body portion 110 may be formed in the interlayer dielectric layer IDL, and a trench penetrating the interlayer dielectric layer IDL may expose the dam body portion 110. The portion of the dam body portion 110 may fill the trench, the portion of the dam body portion 110 may be disposed to vertically overlap the dam body portion 110, and the portion of the dam body portion 110 may be included in the dam body portion 110. After the conductive vias CDV are formed and one layer of the dam body portion 110 is formed, the interlayer dielectric layer IDL may cover the conductive vias CDV and the dam body portion 110 and the first bonding dielectric layer BDL1 may cover the interlayer dielectric layer IDL.

Referring to FIG. 15, the first bonding pads BP1 may be formed in the interlayer dielectric layer IDL and the first bonding dielectric layer BDL1, and the trench penetrating the interlayer dielectric layer IDL and the first bonding dielectric layer BDL1 may expose the conductive vias CDV. The first bonding pads BP1 may fill the trench, and the first bonding pads BP1 may be formed on the conductive vias CDV. The first bonding pads BP1 and the conductive vias CDV may be electrically connected to each other. A portion of the dam body portion 110 may be formed in the interlayer dielectric layer IDL and the first bonding dielectric layer BDL1, and the trench penetrating the interlayer dielectric layer IDL and the first bonding dielectric layer BDL1 may expose the dam body portion 110. The portion of the dam body portion 110 may fill the trench, the portion of the dam body portion 110 may be disposed to vertically overlap the dam body portion 110, and the portion of the dam body portion 110 may be included in the dam body portion 110. The first front surface layer FL1 according to one or more embodiments may include the substrate dielectric layer SDL, the semiconductor devices SD, the device dielectric layer DDL, the conductive vias CDV, the conductive wirings CDW, the dam body portion 110, the first bonding pads BP1, and the first bonding dielectric layer BDL1.

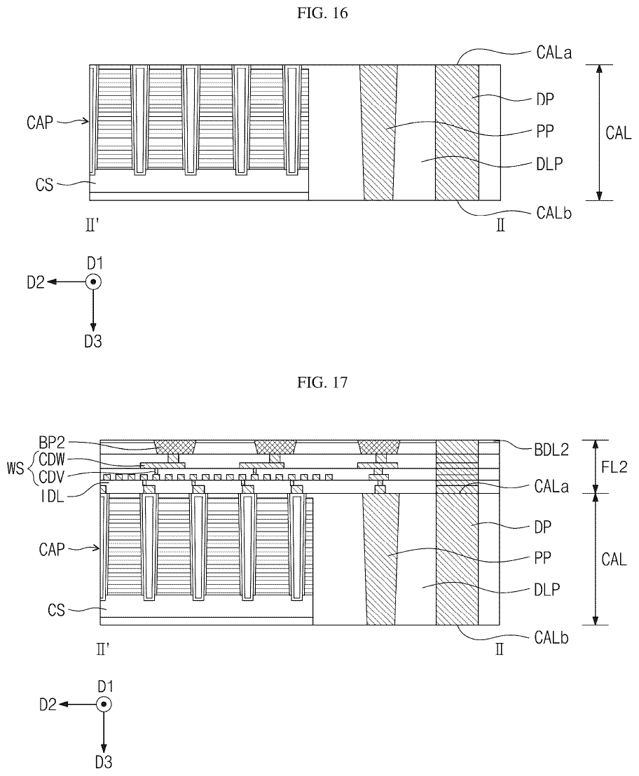

Referring to FIG. 16, a cell substrate CS including at least one layer may be provided, and a cell array portion CAP may be formed on the cell substrate CS. In one or more embodiments, the cell substrate CS may further include a dielectric layer on a surface opposite to the cell array portion CAP. The cell array layer CAL may include the cell array portion CAP, a pad portion PP, a dam portion DP, and a dielectric portion DLP, and the pad portion PP and the dam portion DP may be formed by filling the inside of a trench penetrating the dielectric portion DLP. The cell array layer CAL may have a front surface CALa and a back surface CALb opposing the front surface CALa.

Referring to FIG. 17, a second front surface layer FL2 may be formed on the front surface CALa of the cell array layer CAL. In one or more embodiments, the second front surface layer FL2 may include an interlayer dielectric layer IDL, conductive wirings CDW, conductive vias CDV, second bonding pads BP2, a second bonding dielectric layer BDL2, and a dam body portion 110. As described with reference to FIGS. 11 to 15, the conductive wirings CDW are disposed, the interlayer dielectric layer IDL covers the conductive wirings CDW, the conductive vias CDV are formed in the interlayer dielectric layer IDL, and the process may be repeated to stack at least two layers. The uppermost second front surface layer FL2 may include the second bonding dielectric layer BDL2 and the second bonding pads BP2, and a dam body portion 110 may be included in a portion of the second front surface layer FL2.

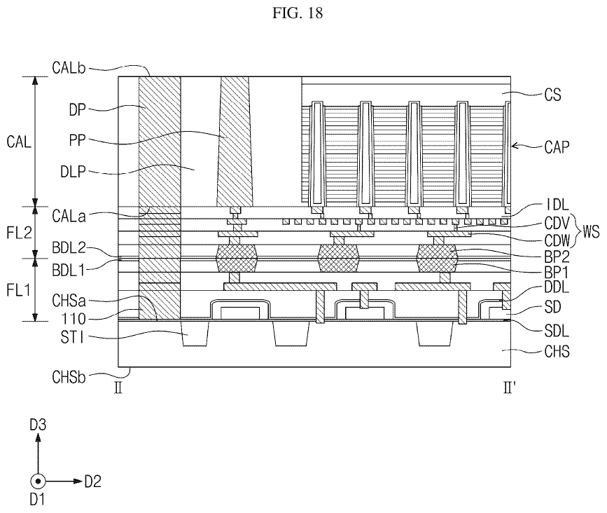

Referring to FIG. 18, a portion of the semiconductor chip of FIG. 15 may be bonded to a portion of the semiconductor chip of FIG. 17. As a result, a single semiconductor chip may be formed. Each of the first bonding pads BP1 may be disposed to vertically overlap each of the second bonding pads BP2, and the bonding pads BP1 and BP2 may be bonded to each other using copper-to-copper bonding. The first bonding dielectric layer BDL1 and the second bonding dielectric layer BDL2 may be bonded to each other by a covalent bond.

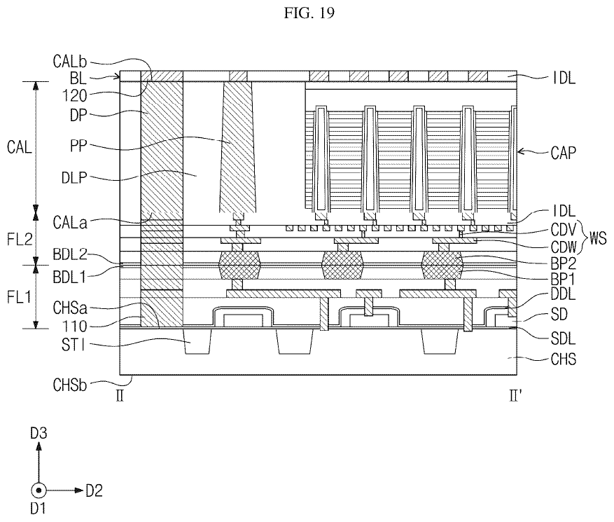

Referring to FIG. 19, the interlayer dielectric layer IDL may cover the back surface CALb of the cell array layer CAL, and the conductive vias CDV and the dam head portion 120 may be formed in the interlayer dielectric layer IDL. The dam head portion 120 may include at least one material different from the dam body portion 110. In one or more embodiments, the dam body portion 110 may be formed of one of aluminum (Al), copper (Cu), nickel (Ni), tungsten (W), silver (Ag), platinum (Pt), and gold (Au), and the dam head portion 120 may be formed of at least one of the remaining materials excluding the material constituting the dam body portion 110. For example, when the dam body portion 110 is formed of tungsten (W), the dam head portion 120 may be formed of at least one of aluminum (Al), copper (Cu), nickel (Ni), silver (Ag), platinum (Pt), and gold (Au). For example, when the dam body portion 110 is formed of aluminum Al, the dam head portion 120 may be formed of at least one of copper (Cu), nickel (Ni), tungsten (W), silver (Ag), platinum (Pt), and gold (Au). The materials constituting the dam body portion 110 and/or the dam head portion 120 are not limited thereto and may be materials used to constitute at least a portion of a semiconductor other than the above-mentioned materials, as long as they have a high thermal conductivity. Therefore, materials applied to a semiconductor, materials having a high thermal conductivity in spite of not being a metallic material, materials having a high thermal conductivity and a low conductivity, or the like, may be used as constituent elements through future research. In one or more embodiments, the dam head portion 120 may be formed of the same or similar materials as the dam body portion 110.

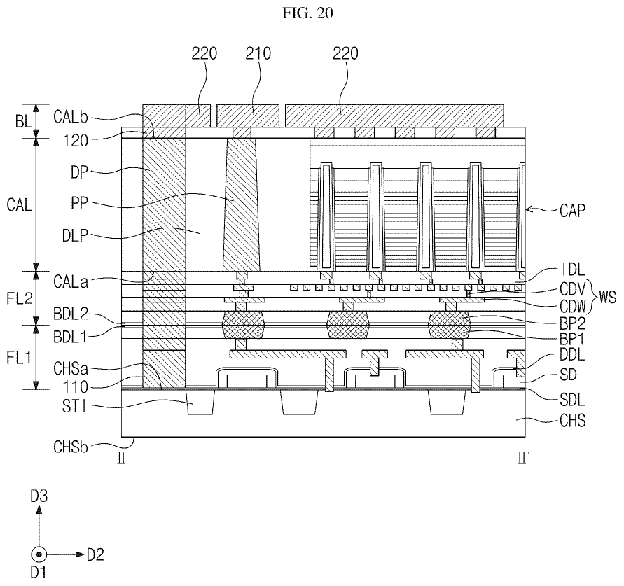

Referring to FIG. 20, a portion of the heat dissipation pad 210 may be disposed at a position vertically overlapping a conductive via CDV connected to the pad portion PP, and the heat dissipation pad 210 may receive heat of the chip substrate CHS through the wiring structure WS. The heat dissipation interface 220 may be disposed to be spaced apart from the heat dissipation pad 210 and surround at least a portion of the heat dissipation pad 210. In one or more embodiments, the heat dissipation interface 220 may be disposed to be spaced apart from the heat dissipation pad 210 and completely surround the heat dissipation pad 210. At least a portion of the heat dissipation interface 220 may be disposed to be in contact with the dam head portion 120, and the heat dissipation interface 220 may provide heat received from the heat dissipation pad 210 to the dam head portion 120. According to one or more embodiments, the semiconductor chip of the present application may provide the heat of the heat dissipation pad 210 to the dam structure 100 by including the heat dissipation interface 220, and may rapidly dissipate the heat by significantly increasing a surface area exposed to the outside of the chip. In addition, the heat dissipation interface 220 may provide heat other than the heat provided from the heat dissipation pad 210, for example, heat directly reaching the heat dissipation interface 220, to the dam structure 100.

A portion of the dam head portion 120 may be formed on the interlayer dielectric layer IDL. The portion of the dam head portion 120 may be disposed to have a portion that vertically overlaps the dam head portion 120, and the portion of the dam head portion 120 may be included in the dam head portion 120. The portion of the dam head portion 120 may be disposed to have a portion that is in contact with the heat dissipation interface 220, and the portion of the dam head portion 120 may also be disposed integrally with the heat dissipation interface 220.

In one or more embodiments, the heat dissipation pad 210, the heat dissipation interface 220, and the portion of the dam head portion 120 may be formed through a single process, so that the heat dissipation pad 210, the heat dissipation interface 220, and the portion of the dam head portion 120 may be formed of the same material. However, it is not limited thereto, and thus the heat dissipation pad 210, the heat dissipation interface 220, and the portion of the dam head portion 120 may include different materials, and may also include some same or similar materials. In addition, the heat dissipation pad 210, the heat dissipation interface 220, and the portion of the dam head portion 120 may be formed through a single process, and thus the heat dissipation pad 210, the heat dissipation interface 220, and the portion of the dam head portion 120 may be disposed at points corresponding to the same or similar location level. For example, an upper surface of the heat dissipation pad 210, an upper surface of the heat dissipation interface 220, and an upper surface of the dam head portion 120 may be coplanar and may have substantially the same location level.

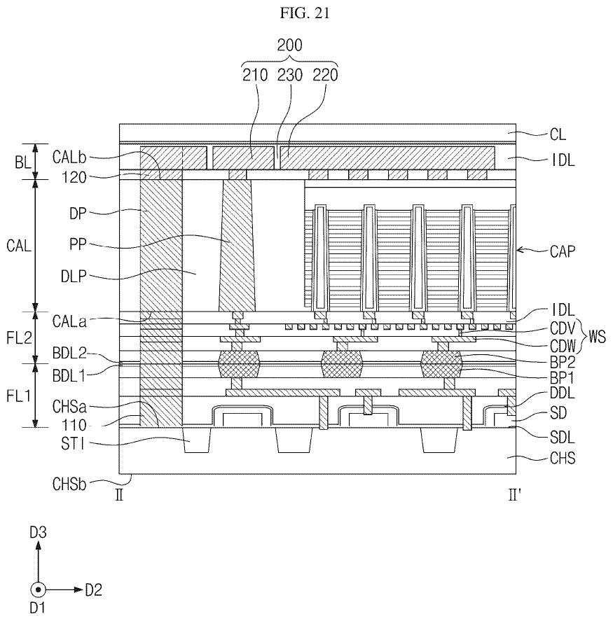

Referring to FIG. 21, the interlayer dielectric layer IDL may cover the heat dissipation pad 210, the heat dissipation interface 220, and the dam head portion 120, and as the interlayer dielectric layer IDL is provided between the heat dissipation pad 210 and the heat dissipation interface 220, the pad dielectric layer 230 may be formed. The pad dielectric layer 230 may be disposed between the heat dissipation pad 210 and the heat dissipation interface 220, and the pad dielectric layer 230 may substantially reduce an electrical connection between the heat dissipation pad 210 and the heat dissipation interface 220. A cover layer CL may cover the uppermost back surface layer BL and may be formed of at least one insulating material.

Referring to FIGS. 2, 4, 5, and 21, an opening OP may be formed in the cover layer CL. The opening OP may be formed when a portion of the cover layer CL that vertically overlaps the heat dissipation pad 210 and/or the conductive pads 300 is recessed.

Embodiments of the present disclosure relate to a method of manufacturing a semiconductor chip, which may include preparing a chip substrate having a front surface and a back surface opposing the front surface, forming a cell array portion on the front surface of the chip substrate, forming a dam structure to surround the cell array portion on the front surface of the chip substrate, forming a heat dissipation wiring structure on the front surface of the chip substrate, forming a heat dissipation pad on the heat dissipation wiring structure, forming a heat dissipation interface to surround the heat dissipation pad, and forming a pad dielectric layer between the heat dissipation pad and the heat dissipation interface.

The heat dissipation pad may be disposed between the cell array portion and the dam structure in plan view.

The method may further include forming a conductive wiring structure on the front surface of the chip substrate before forming the heat dissipation pad, and may further include forming a conductive pad on the conductive wiring structure before forming the heat dissipation interface.

Forming the dam structure may include forming a dam body portion on the front surface of the chip substrate and forming a dam head portion on the dam body portion.

A level of an upper surface of the dam head portion may be substantially the same as a level of an upper surface of the heat dissipation interface.

The dam head portion may include a material that is substantially the same as a material of the heat dissipation pad and a material of the heat dissipation interface.

The pad dielectric layer may completely surround the entire heat dissipation pad in plan view, and the heat dissipation interface may completely surround the entire pad dielectric layer in plan view.

The method may further include forming a cover layer on the semiconductor chip.

The method may further include forming an opening to penetrate through the cover layer, and the opening may vertically overlap the heat dissipation pad.

At least a portion of the heat dissipation interface may be disposed on the cell array portion, and a dielectric material may be further included between the heat dissipation interface and the cell array portion.

According to the above-described semiconductor package, heat generated inside the semiconductor chip may be transferred to the outside of the semiconductor chip through the heat dissipation pad 210, and the transferred heat may be transferred to the dam structure 100 through the heat dissipation interface 220. For example, the semiconductor package SPK may include the heat dissipation interface 220 to provide the heat of the heat dissipation pad 210 to the dam structure 100, and may significantly increase a surface area exposed to the outside of the chip to rapidly dissipate the heat. As a result, the semiconductor package may reduce or significantly reduce the accumulation of heat generated in the semiconductor chips stacked in the semiconductor package.

As set forth above, according to embodiments, a semiconductor package may reduce heat generated therein.

While various embodiments have been shown and described above, it will be apparent to those skilled in the art that modifications and variations could be made without departing from the scope of the present disclosed concepts as defined by the appended claims.

What is claimed is:

1. A semiconductor chip comprising:
a chip substrate having a front surface and a back surface opposing the front surface;
a cell array portion disposed on the front surface of the chip substrate;
a dam structure disposed on the front surface of the chip substrate and surrounding the cell array portion;
a heat dissipation wiring structure provided on the front surface of the chip substrate;
a heat dissipation pad disposed on the heat dissipation wiring structure, and disposed between the cell array portion and the dam structure in plan view;
a pad dielectric layer surrounding at least a portion of the heat dissipation pad; and
a heat dissipation interface connecting the dam structure and the pad dielectric layer.

2. The semiconductor chip of claim 1, further comprising:
a conductive wiring structure provided on the front surface of the chip substrate; and
a conductive pad disposed on the conductive wiring structure, and disposed between the cell array portion and the dam structure in plan view.

3. The semiconductor chip of claim 1, wherein:
the dam structure comprises a dam body portion disposed on the front surface of the chip substrate, and a dam head portion disposed on the dam body portion.

4. The semiconductor chip of claim 3, wherein:
a level of an upper surface of the dam head portion is the same as a level of an upper surface of the heat dissipation interface.

5. The semiconductor chip of claim 4, wherein:
the heat dissipation interface is integral with the dam head portion.

6. The semiconductor chip of claim 3, wherein:
the dam body portion comprises a material, different from a material of the dam head portion.

7. The semiconductor chip of claim 6, wherein:
the dam head portion comprises the same material as a material of the heat dissipation pad and the heat dissipation interface.

8. The semiconductor chip of claim 1, wherein:
the pad dielectric layer surrounds an entirety of the heat dissipation pad in plan view; and
the heat dissipation interface surrounds an entirety of the pad dielectric layer in plan view.

9. The semiconductor chip of claim 1, further comprising:
a cover layer disposed on the cell array portion, the dam structure, the heat dissipation pad, the pad dielectric layer, and the heat dissipation interface.

10. The semiconductor chip of claim 9, further comprising:
an opening penetrating through the cover layer, the opening vertically overlapping the heat dissipation pad.

11. The semiconductor chip of claim 1, wherein:
at least a portion of the heat dissipation interface is disposed on the cell array portion; and
the semiconductor chip further comprises an insulating material between the heat dissipation interface and the cell array portion.

12. A semiconductor chip comprising:
a chip substrate having a front surface and a back surface opposing the front surface;
a cell array portion disposed on the front surface of the chip substrate;
a dam structure disposed on the front surface of the chip substrate and surrounding the cell array portion, the dam structure comprising a dam body portion disposed on the front surface of the chip substrate and a dam head portion disposed on the dam body portion;
a conductive wiring structure provided on the front surface of the chip substrate;
a conductive pad disposed on the conductive wiring structure, and disposed between the cell array portion and the dam structure in plan view;
a heat dissipation interface extending from the dam head portion to be disposed on the cell array portion; and
an insulating material disposed between the heat dissipation interface and the cell array portion.

13. The semiconductor chip of claim 12, wherein:
the dam body portion comprises a material, different from a material of the dam head portion.

14. The semiconductor chip of claim 12, further comprising:
a heat dissipation wiring structure provided on the front surface of the chip substrate; and
a heat dissipation pad disposed on the heat dissipation wiring structure, and disposed between the cell array portion and the dam structure in plan view.

15. The semiconductor chip of claim 14, further comprising:
a cover layer disposed on the cell array portion, the dam head portion, the heat dissipation pad, the insulating material, and the heat dissipation interface.

16. The semiconductor chip of claim 15, further comprising:
an opening penetrating through the cover layer, the opening vertically overlapping the heat dissipation pad and the conductive pad.

17. A semiconductor package comprising:
a plurality of stacked semiconductor chips,
wherein:
at least one of the semiconductor chips comprises:
a chip substrate;
a cell array portion disposed on one surface of the chip substrate;
a dam structure disposed on the one surface of the chip substrate and surrounding the cell array portion;
a heat dissipation wiring structure provided on the one surface of the chip substrate;
a heat dissipation pad disposed on the heat dissipation wiring structure, and disposed between the cell array portion and the dam structure in plan view; and
a pad dielectric layer surrounding at least a portion of the heat dissipation pad;
the heat dissipation pad extends toward the dam structure to allow the pad dielectric layer to be in contact with the dam structure; and
the semiconductor chips are stacked to expose the heat dissipation pad.

18. The semiconductor package of claim 17, further comprising:
a heat dissipation interface extending from the dam structure to be disposed on the cell array portion.

19. The semiconductor package of claim 17, comprising:
a conductive wiring structure provided on the one surface of the chip substrate; and
a conductive pad disposed on the conductive wiring structure, and disposed between the cell array portion and the dam structure in plan view.

20. The semiconductor package of claim 19, wherein:
the heat dissipation pad has a size larger than a size of the conductive pad in plan view.
